(19) United States
(12) Patent Application Publication
(10) Pub. No.: US 2024/0420644 A1
(43) Pub. Date: Dec. 19, 2024

(54) Display having Gate Driver Circuitry with Reduced Power Consumption and Improved Reliability

(71) Applicant: Apple Inc., Cupertino, CA (US)

(72) Inventors: Fan Gui, Sunnyvale, CA (US); Chin-Wei Lin, San Jose, CA (US); Aida R Colon-Berrios, Cupertino, CA (US); Ran Tu, Palo Alto, CA (US); Xuan Hu, San Jose, CA (US); Levent Erdal Aygun, Santa Clara, CA (US); Yi Zhao, San Jose, CA (US)

(21) Appl. No.: 18/657,870

(22) Filed: May 8, 2024

Related U.S. Application Data
(60) Provisional application No. 63/507,775, filed on Jun. 13, 2023.

(51) Int. Cl. G09G 3/3266

(52) U.S. Cl. CPC G09G 3/3266; G09G 2310/08; G09G 2320/0247; G09G 2330/021

(57) ABSTRACT

A display may include an array of pixels that receive control signals from a chain of gate drivers. Each gate driver may include a mix of silicon transistors, one or more semiconducting oxide transistors, and one or more capacitors. The semiconducting oxide transistors can each have a back gate terminal shorted to one of its source-drain terminals, shorted to its front gate terminal, or configured to receive a bias voltage. Configured in this way, the gate driver circuit can exhibit less threshold voltage drift and thus improved device reliability over time.

This application claims the benefit of U.S. Provisional Patent Application No. 63/507,775, filed Jun. 13, 2023, which is hereby incorporated by reference herein in its entirety.

### FIELD

This relates generally to electronic devices and, more particularly, to electronic devices with displays.

### BACKGROUND

Electronic devices can include displays. For example, cellular telephones, tablets, wrist-watches, and portable computers often include displays for presenting image content to users. Displays such as organic light-emitting diode (OLED) displays have an array of display pixels based on light-emitting diodes. In this type of display, gate driver circuitry can be used to provide control signals to respective rows in the array of display pixels. It can be challenging to design the gate driver circuitry.

### SUMMARY

An electronic device may include a display having an array of display pixels. The display pixels may be organic light-emitting diode display pixels. Each display pixel may include at least an organic light-emitting diode (OLED) that emits light and associated semiconducting oxide transistors. The array of display pixels may receive control signals such as gate output signals from peripheral gate driver circuitry. The gate driver circuitry may include a chain of gate driver circuits.

An aspect of the disclosure provides a gate driver circuit that includes: a first transistor having a drain terminal coupled to a first power supply line, a source terminal coupled to an output port of the gate driver circuit, and a gate terminal, where a gate output signal is generated at the output port and is provided to a plurality of display pixels; a second transistor having a drain terminal coupled to the output port, a source terminal coupled to a second power supply line different than the first power supply line, and a gate terminal; and a semiconducting oxide transistor having a source terminal coupled to the first power supply line or configured to receive a bias voltage, a drain terminal coupled to the gate terminal of the second transistor, a back gate terminal shorted to its source terminal, and a front gate terminal.

An aspect of the disclosure provides a gate driver circuit that includes: a first semiconducting oxide transistor having a source terminal coupled to a first power supply line, a drain terminal coupled to an output port of the gate driver circuit, a front gate terminal coupled to a first node, and a back gate terminal configured to receive a bias voltage; a first silicon transistor having a drain terminal coupled to the output port, a gate terminal coupled to the first node, and a source terminal coupled to a second power supply line different than the first power supply line; and a capacitor having a first terminal coupled to the first node and having a second terminal coupled to the second power supply line.

An aspect of the disclosure provides a gate driver circuit that includes: a first semiconducting oxide transistor having a source terminal coupled to a first power supply line, a drain terminal coupled to an output port of the gate driver circuit, a front gate terminal, and a back gate terminal that is configured to receive a bias voltage; a first silicon transistor having a drain terminal coupled to the output port, a source terminal coupled to a second power supply line different than the first power supply line, and a gate terminal; an inverter having an output coupled to the gate terminal of the first silicon transistor; and a capacitor having a first terminal coupled to an input of the inverter and having a second terminal coupled to the second power supply line.

An aspect of the disclosure provides a gate driver circuit that includes: a first semiconducting oxide transistor having a source terminal coupled to a first power supply line, a drain terminal coupled to an output port of the gate driver circuit, a front gate terminal coupled to a first node, and a back gate terminal configured to receive a bias voltage; a first silicon transistor having a drain terminal coupled to the output port, a gate terminal coupled to the first node, and a source terminal coupled to a second power supply line different than the first power supply line; and a logic subcircuit configured to generate a carry signal on the first node, wherein the carry signal is conveyed to an additional gate driver circuit.

An aspect of the disclosure provides a gate driver circuit that includes: a first semiconducting oxide transistor having a first source-drain terminal configured to receive a first clock signal, a second source-drain terminal coupled to an output port of the gate driver circuit, a front gate terminal coupled to a first node, and a back gate terminal; a first capacitor coupled across the first node and the output port; a second semiconducting oxide transistor having a drain terminal coupled to the output port, a source terminal coupled to a first power supply line, a front gate terminal coupled to a second node, and a back gate terminal; and a second capacitor coupled across the second node and the first power supply line.

### BRIEF DESCRIPTION OF THE DRAWINGS

FIG. 1 is a diagram of an illustrative electronic device having a display in accordance with some embodiments.

FIG. 2 is a diagram of an illustrative display having an array of organic light-emitting diode display pixels in accordance with some embodiments.

FIG. 3 is a circuit diagram of an illustrative display pixel in accordance with some embodiments.

FIGS. 4A-4D are circuit diagrams of illustrative gate driver circuits in accordance with some embodiments.

FIG. 5 is a diagram showing a chain of gate driver circuits of the type shown in FIGS. 4A-4D in accordance with some embodiments.

FIGS. 6A and 6B are timing diagrams illustrating the operation of gate driver circuits of the type shown in FIG. 5 in accordance with some embodiments.

FIGS. 7A and 7B are circuit diagrams of illustrative gate driver circuits in accordance with some embodiments.

FIG. 8 is a diagram showing a chain of gate driver circuits of the type shown in FIGS. 7A and 7B in accordance with some embodiments.

FIGS. 9A, 9B, and 9C are timing diagrams illustrating the operation of gate driver circuits of the type shown in FIG. 8 in accordance with some embodiments.

FIG. 10A is a circuit diagram of an illustrative gate driver circuit having a logic subcircuit and an output buffer subcircuit in accordance with some embodiments.

FIG. 10B is a timing diagram illustrating the operation of the gate driver circuit shown in FIG. 10A in accordance with some embodiments.

FIG. 11A is a circuit diagram of an illustrative gate driver circuit having a logic subcircuit and an output buffer subcircuit in accordance with some embodiments.

FIG. 11B is a timing diagram illustrating the operation of the gate driver circuit shown in FIG. 11A in accordance with some embodiments.

### DETAILED DESCRIPTION

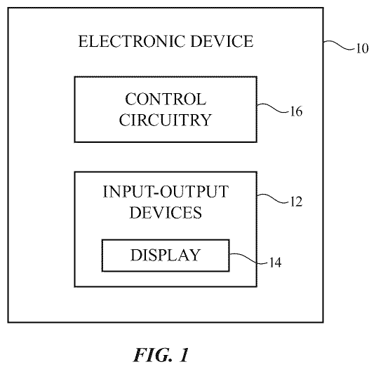

An illustrative electronic device of the type that may be provided with a display is shown in FIG. 1. As shown in FIG. 1, electronic device 10 may have control circuitry 16. Control circuitry 16 may include storage and processing circuitry for supporting the operation of device 10. The storage and processing circuitry may include storage such as hard disk drive storage, nonvolatile memory (e.g., flash memory or other electrically-programmable-read-only memory configured to form a solid state drive), volatile memory (e.g., static or dynamic random-access-memory), etc. Processing circuitry in control circuitry 16 may be used to control the operation of device 10. The processing circuitry may be based on one or more microprocessors, application processors, microcontrollers, digital signal processors, baseband processors, power management units, audio chips, application specific integrated circuits, etc.

Input-output circuitry in device 10 such as input-output devices 12 may be used to allow data to be supplied to device 10 and to allow data to be provided from device 10 to external devices. Input-output devices 12 may include buttons, joysticks, scrolling wheels, touch pads, key pads, keyboards, microphones, speakers, tone generators, vibrators, cameras, sensors, light-emitting diodes and other status indicators, data ports, etc. A user can control the operation of device 10 by supplying commands through input-output devices 12 and may receive status information and other output from device 10 using the output resources of input-output devices 12.

Input-output devices 12 may include one or more displays such as display 14. Display 14 may be a touch screen display that includes a touch sensor for gathering touch input from a user or display 14 may be insensitive to touch. A touch sensor for display 14 may be based on an array of capacitive touch sensor electrodes, acoustic touch sensor structures, resistive touch components, force-based touch sensor structures, a light-based touch sensor, or other suitable touch sensor arrangements.

Control circuitry 16 may be used to run software on device 10 such as operating system code and applications. During operation of device 10, the software running on control circuitry 16 may display images on display 14 using an array of pixels in display 14. Device 10 may be a tablet computer, laptop computer, a desktop computer, a display, a cellular telephone, a media player, a wristwatch device or other wearable electronic equipment, or other suitable electronic device.

Display 14 may be an organic light-emitting diode display or may be a display based on other types of display technology. Configurations in which display 14 is an organic light-emitting diode (OLED) display are sometimes described herein as an example. This is, however, merely illustrative. Any suitable type of display may be used in device 10, if desired.

Display 14 may have a rectangular shape (i.e., display 14 may have a rectangular footprint and a rectangular peripheral edge that runs around the rectangular footprint) or may have other suitable shapes. Display 14 may be planar or may have a curved profile.

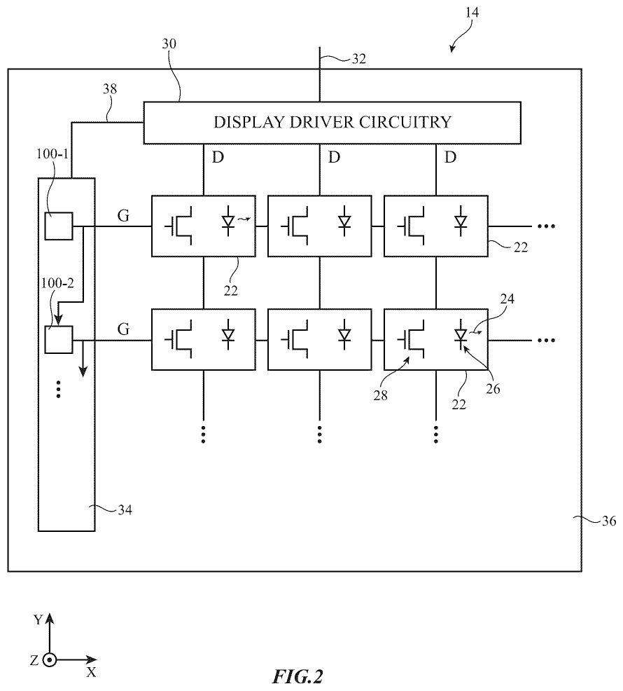

A top view of a portion of display 14 is shown in FIG. 2. As shown in FIG. 2, display 14 may have an array of pixels 22 formed on a substrate 36. Substrate 36 may be formed from glass, metal, plastic, ceramic, porcelain, or other substrate materials. Pixels 22 may receive data signals over signal paths such as data lines D (sometimes referred to as data signal lines, column lines, etc.) and may receive one or more control signals over control signal paths such as horizontal control lines G (sometimes referred to as gate lines, scan lines, emission lines, row lines, etc.). There may be any suitable number of rows and columns of pixels 22 in display 14 (e.g., tens or more, hundreds or more, or thousands or more).

Each pixel 22 may have a light-emitting diode 26 that emits light 24 under the control of a pixel control circuit formed from thin-film transistor circuitry such as thin-film transistors 28 and thin-film capacitors). Thin-film transistors 28 may be polysilicon thin-film transistors, semiconducting oxide thin-film transistors such as indium zinc gallium oxide transistors, or thin-film transistors formed from other semiconductors. Pixels 22 may contain light-emitting diodes of different colors (e.g., red, green, and blue) to provide display 14 with the ability to display color images.

Display driver circuitry 30 may be used to control the operation of pixels 22. The display driver circuitry 30 may be formed from integrated circuits, thin-film transistor circuits, or other suitable electronic circuitry. Display driver circuitry 30 of FIG. 2 may contain communications circuitry for communicating with system control circuitry such as control circuitry 16 of FIG. 1 over path 32. Path 32 may be formed from traces on a flexible printed circuit or other cable. During operation, the control circuitry (e.g., control circuitry 16 of FIG. 1) may supply circuitry 30 with information on images to be displayed on display 14.

To display the images on display pixels 22, display driver circuitry 30 may supply image data to data lines D (e.g., data lines that run down the columns of pixels 22) while issuing clock signals and other control signals to supporting display driver circuitry such as gate driver circuitry 34 over path 38. If desired, display driver circuitry 30 may also supply clock signals and other control signals to gate driver circuitry 34 on an opposing edge of display 14 (e.g., the gate driver circuitry may be formed on more than one side of the display pixel array).

Gate driver circuitry 34 (sometimes referred to as horizontal line control circuitry or row driver circuitry) may be implemented as part of an integrated circuit and/or may be implemented using thin-film transistor circuitry. Horizontal/row control lines G in display 14 may carry gate line signals (scan line control signals), emission enable control signals, and/or other horizontal control signals for controlling the pixels of each row. There may be any suitable number of horizontal control signals per row of pixels 22 (e.g., one or more row control lines, two or more row control lines, three or more row control lines, four or more row control lines, five or more row control lines, etc.). Gate driver circuitry 34 may include multiple gate driver circuits (e.g., gate drivers 100-1, 100-2, and so on) connected in a chain. For example, each gate driver may be configured to generate one or more scan signals and/or carry signals that are fed forward to a succeeding gate driver in the chain and/or that are fed back to a preceding gate driver in the chain.

In accordance with some embodiments, pixels 22 and gate driver circuitry 34 may be implemented using thin-film transistors such as semiconducting oxide transistors. A “semiconducting oxide transistor” can refer to and be defined herein as a thin-film transistor having a channel region formed from semiconducting oxide material (e.g., indium gallium zinc oxide or IGZO, indium tin zinc oxide or ITZO, indium gallium tin zinc oxide or IGTZO, indium tin oxide or ITO, or other semiconducting oxide material). Semiconducting oxide transistors are generally considered n-type (n-channel) transistors.

A semiconducting oxide transistor is notably different than a silicon transistor. A “silicon transistor” can refer to and be defined herein as a thin-film transistor having a polysilicon channel region deposited using a low temperature process sometimes referred to as LTPS or low-temperature polysilicon. Semiconducting oxide transistors exhibit lower leakage than silicon transistors, so implementing at least some of the transistors within pixel 22 can help reduce flicker (e.g., by preventing current from leaking away from the gate terminal of drive transistor Tdrive). In some embodiments, pixels 22 and gate driver circuitry 34 may be formed using only semiconducting oxide transistors (i.e., display 14 does not include any silicon transistors). In other embodiments, at least some of the transistors within pixel 22 and/or gate driver circuitry 34 may be implemented as silicon transistors such that pixel 22 and/or gate driver circuitry 34 includes a combination of semiconducting oxide transistors and silicon transistors (e.g., n-type LTPS transistors or p-type LTPS transistors).

Different transistors within display 14 may require different device characteristics for optimal display performance and operation. For instance, transistors that are predominantly in the off state may require more negative-bias-temperature-stress (NBTS) stability. As another example, transistors that are predominantly in the on state may require more positive-bias-temperature-stress (PBTS) stability. At least some transistors within gate driver circuitry 34 may benefit from better PBTS and higher mobility for enhance drive-ability.

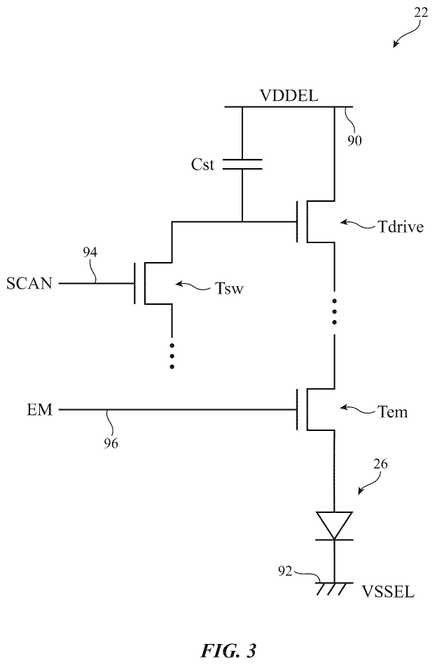

FIG. 3 is a circuit diagram of an illustrative display pixel such as organic light-emitting diode (OLED) pixel 22 in display 14. As shown in FIG. 3, display pixel 22 may include an organic light-emitting diode 26, a storage capacitor Cst, and associated pixel transistors such as a drive transistor Tdrive, a switching transistor Tsw, and an emission transistor Tem. Any number of these transistors may be implemented as a semiconducting-oxide transistor (e.g., a transistor with an n-type channel formed from semiconducting oxide such as indium gallium zinc oxide or IGZO) or as a silicon transistor (e.g., a transistor with a polysilicon channel deposited using a low temperature process, sometimes referred to as “LTPS” or low-temperature polysilicon transistor). In particular, switching transistor Tsw may be implemented as a semiconducting-oxide transistor (sometimes referred to as an “oxide transistor”). Semiconducting-oxide transistors exhibit relatively lower leakage than silicon transistors, so implementing switching transistor Tsw as a semiconducting-oxide transistor will help reduce flicker (e.g., by preventing current from leaking away from the gate terminal of the drive transistor Tdrive).

In the example of FIG. 3, the drive transistor Tdrive, emission transistor Tem, and diode 26 may be coupled in series between power supply terminals 90 and 92. A positive power supply voltage VDDEL may be supplied to positive power supply terminal 90, whereas a ground power supply voltage VSSEL may be supplied to ground power supply terminal 92. Positive power supply voltage VDDEL may be 3 V, 4 V, 5 V, 6 V, 7 V, 2 to 8 V, more than 10 V, or any suitable positive power supply voltage level. Ground power supply voltage VSSEL may be 0 V, −1 V, −2 V, −3 V, −4 V, −5 V, −6V, −7 V, less than −10 V, or any suitable ground or negative power supply voltage level. The state of drive transistor Tdrive controls the amount of current flowing from terminal 90 to terminal 92 through diode 26 and therefore controls the amount of light emitted from display pixel 22.

Control signals from display driver circuitry such as row driver circuitry 34 of FIG. 2 are supplied to control terminals such as row control terminals 94 and 96. Row control terminal 96 may serve as an emission control terminal (sometimes referred to as an emission line or emission control line), whereas row control terminal 94 may serve as a scan control terminal (sometimes referred to as a scan line or scan control line). Emission control signal EM, sometimes referred to as an emission signal, may be supplied to terminal 96. Emission signal EM can be asserted to turn on transistor Tem during an emission phase to allow current to flow from the drive transistor Tdrive down to light-emitting diode 26. Scan control signal SCAN may be applied to scan line 94. Asserting signal SCAN may turn on transistor Tsw, which connects the gate and drain terminals of transistor Tdrive. Deasserting signal SCAN will turn off transistor Tsw, which decouples the gate and drain terminals of transistor Tdrive. During a data loading phase, a data signal (voltage) can be loaded onto the storage capacitor Cst (e.g., using a separate data loading transistor, not shown). Image data that is loaded into pixel 22 can be at least partially stored on pixel 22 using capacitor Cst to hold charge throughout the emission phase.

The pixel structure of FIG. 3 is illustrative and not intended to limit the scope of the present embodiments. If desired, pixel 22 may include more or less than three thin-film transistors (e.g., including one or more additional emission transistor, initialization transistor, data loading transistor, anode reset transistor, bias transistor, etc.) and/or may include more or less than one capacitor.

A conventional gate driver circuit can include only silicon thin-film transistors (i.e., all of the transistors within a gate driver are p-type LTPS transistors) and a large capacitor coupled to a clock terminal configured to receive a clock signal. Having a large capacitor loading the clock terminal substantially increases the dynamic power consumption of the gate driver circuit since a significant amount of power is needed to charge and discharge the large capacitor in each gate driver circuit as the clock signal toggles. Other types of gate driver circuits having only p-type LTPS transistors and no large capacitor loading the clock terminal might exhibit lower power consumption but has difficulty generating short positive gate pulses.

In accordance with an embodiment, a gate driver circuit such as gate driver 100 is provided that has minimal capacitance loading on the clock terminal (thus reducing power consumption). Gate driver circuit 100 can also include a mix of both silicon transistors and one or more semiconducting oxide transistors. At least one of the semiconducting oxide transistors in gate driver circuit 100 can have a front (top) gate terminal and optionally a back (bottom) gate terminal configured to receive a DC (direct current) voltage or is coupled to a source-drain terminal for improved reliability.

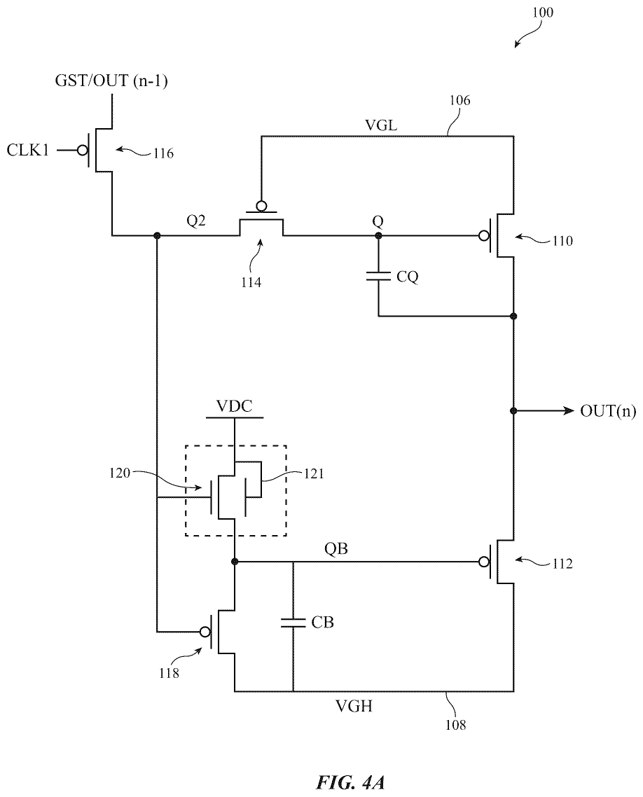

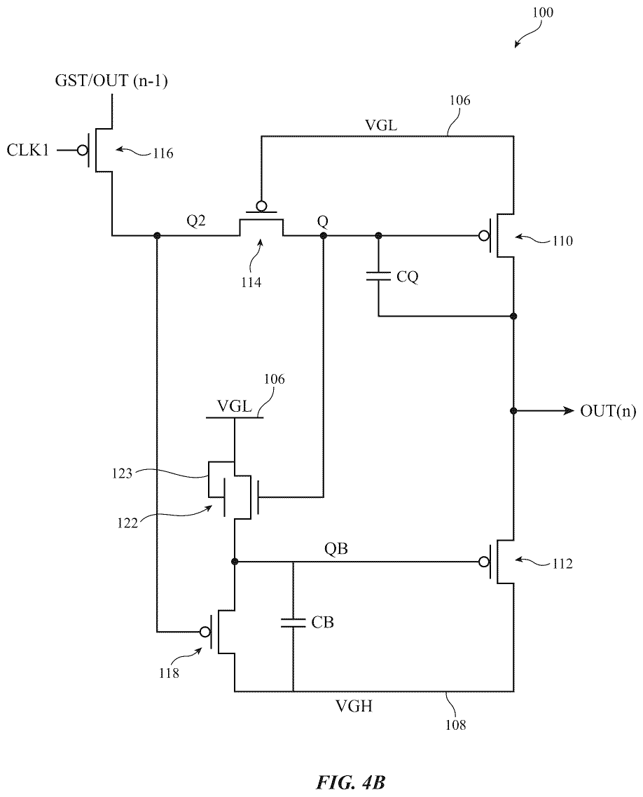

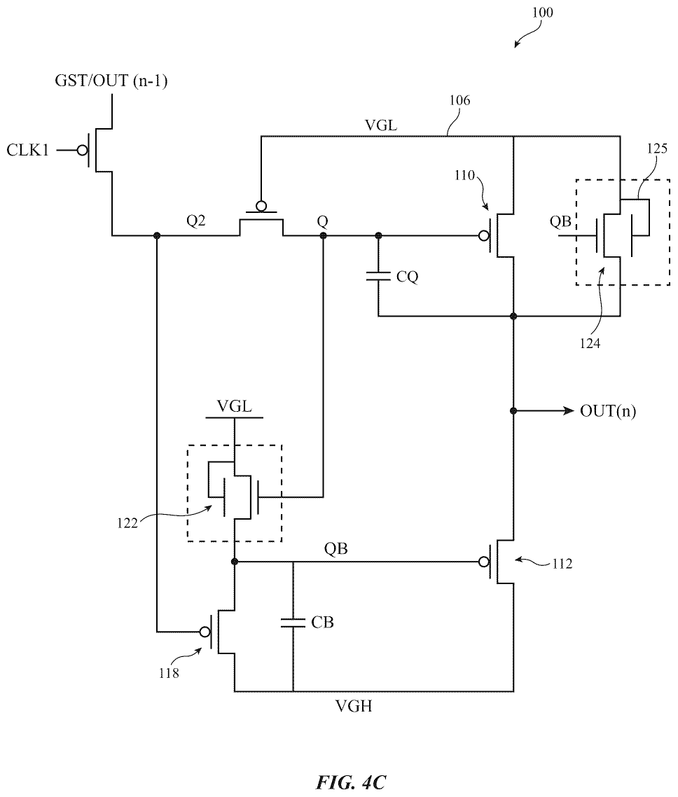

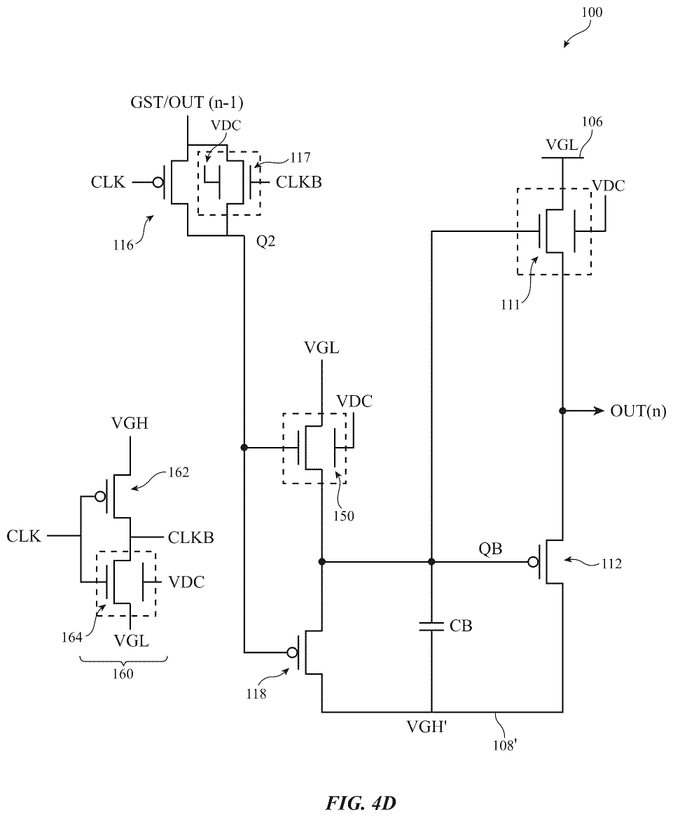

FIG. 4A is a circuit diagram showing one implementation of gate driver circuit 100. As show in FIG. 4A, gate driver circuit 100 can include silicon transistors 110, 112, 114, 116, and 118 (e.g., p-type LTPS transistors), a semiconducting oxide transistor 120 (e.g., an n-type oxide transistor), and capacitors CQ and CB. Transistor 110 can have a drain terminal coupled to ground power supply line 106 (e.g., a power supply terminal on which low voltage VGL is provided), a gate terminal coupled to node Q, and a source terminal coupled to an output port of gate driver circuit 100. For example, power supply voltage VGL may be −5 V, −10 V, −15 V, −20 V, −5 to −15 V, less than −15 V, 0 V, +1 V, +2 V, or other suitable low voltage level. The terms “source” and “drain” are sometimes used interchangeably when referring to current-conducting terminals of a thin-film transistor. Capacitor CQ may be coupled across the gate and source terminals of transistor 110. The source and drain terminals are therefore sometimes referred to as “source-drain” terminals (e.g., a transistor has a gate terminal, a first source-drain terminal, and a second source-drain terminal).

A gate output signal OUT (n) can be generated on the output port. Gate output signal OUT (n) can represent a scan control signal for controlling corresponding switching transistors in one or more rows of pixels 22 or an emission control signal for controlling corresponding emission transistors in one or more rows of pixels 22. The notation “(n)” represents a current row in the display pixel array. Thus, the notation “(n−1)” can refer to circuitry associated with a preceding row in the display pixel array, whereas the notation “(n+1)” might refer to circuitry associated with a succeeding row in the display pixel array.

Transistor 112 can have a drain terminal coupled to the output port of gate driver circuit 100, a gate terminal coupled to node QB, and a source terminal coupled to positive power supply line 108 (e.g., a power supply terminal on which high voltage VGH is provided). For example, power supply voltage VGH may be 5 V, 10 V, 15 V, 20 V, 5 to 10 V, 10 to 15 V, more than 15 V, or other suitable high voltage level. Capacitor CB may be coupled across the gate and source terminals of transistor 112. Transistors 110 and 112 that are directly coupled to the output port are sometimes referred to as output transistors. The voltage on node QB may be inverted with respect to the voltage on node Q (e.g., when the voltage on node Q is high, the voltage on node QB will be low, or vice versa).

Transistor 114 may have a first source-drain terminal coupled to node Q, a gate terminal coupled to the VGL power line 106, and a second source-drain terminal coupled to node Q2. Transistor 116 may have a first source-drain terminal coupled to node Q2, a gate terminal configured to receive clock signal CLK1, and a second source-drain terminal configured to receive a gate start signal GST (e.g., if gate driver circuit 100 is the first or second driver in the gate driver chain) or signal OUT(n−1), which is the gate output signal from the gate driver circuit in a preceding row. Transistor 118 may have a gate terminal coupled to node Q2, a first source-drain terminal coupled to node QB, and a second source-drain terminal coupled to the VGH power line 108.

In accordance with the embodiment of FIG. 4A, semiconducting oxide transistor 120 may have a front gate terminal coupled to node Q2, a drain terminal coupled to node QB, a source terminal configured to receive a bias voltage VDC, and a back (bottom) gate terminal shorted to its source terminal (see source connection path 121). In a thin-film display stackup, the front gate terminal is formed from a conductive layer above the semiconducting oxide layer and is therefore sometimes referred to as the top gate conductor. On the other hand, the back gate terminal can be formed from a conductive layer below the semiconductive oxide layer and is therefore sometimes referred to as the bottom gate conductive. Voltage VDC can represent a static voltage that is preferably higher than low voltage VGL. Biasing transistor 120 in this way enables transistor 120 to exhibit less threshold voltage shift over time, which is technically advantageous and beneficial by improving the overall reliability of gate driver circuit 100. In other examples, voltage VDC can be equal to VGL, less than VGL, equal to VGH, between VGL and VGH, or other fixed DC (direct current) voltage or adjustable voltage. Moreover, the gate terminal of transistor 116 that receives clock signal CLK1 has minimal capacitive loading, which helps to reduce the overall dynamic power consumption of gate driver circuit 100.

The embodiment of FIG. 4A in which gate driver circuit 100 has a semiconducting oxide transistor 120 configured to receive voltage VDC is exemplary. FIG. 4B shows another embodiment of gate driver circuit 100 having a semiconducting oxide transistor 122 having a drain terminal coupled to node QB, a source terminal coupled to the VGL power line 106, a front gate terminal coupled to node Q, and a back gate terminal shorted to its source terminal (see source connection 123). The remaining circuit structure of gate driver 100 of FIG. 4B is identical to that already described in connection with FIG. 4A and need not be reiterated in detail to avoid obscuring the present embodiment. Compared to the embodiment of FIG. 4A, gate driver circuit 100 of FIG. 4B omits the extra VDC voltage line, which simplifies the overall circuit complexity. Connecting the back gate terminal of semiconducting oxide transistor 122 to VGL in this way enables transistor 122 to exhibit less threshold voltage shift over time, which is technically advantageous and beneficial by improving the overall reliability of gate driver circuit 100. Similar to the embodiment of FIG. 4A, the gate terminal of transistor 116 that receives clock signal CLK1 has minimal capacitive loading, which reduces the overall dynamic power consumption of gate driver circuit 100 in FIG. 4B.

The embodiment of FIG. 4B in which gate driver circuit 100 includes only one semiconducting oxide transistor 122 is exemplary. FIG. 4C shows another embodiment of gate driver circuit 100 having an additional (second) semiconducting oxide transistor such as transistor 124. As shown in FIG. 4C, semiconducting oxide transistor 124 may have a source terminal coupled to the VGL power line 106, a drain terminal coupled to the output port of gate driver circuit 100, a front gate terminal coupled to node QB, and a back gate terminal shorted to its own source terminal (see source connection 125). Configured in this way, n-type semiconducting oxide transistor 124 can serve as a dedicated pull-down transistor that, when activated, drives the gate output signal OUT(n) low.

The remaining circuit structure of gate driver 100 of FIG. 4C is identical to that already described in connection with FIG. 4B and need not be reiterated in detail to avoid obscuring the present embodiment. Compared to the embodiment of FIG. 4B, gate driver circuit 100 of FIG. 4C can be operable at an even smaller VGH minus VGL range, thus minimizing the static power consumption of gate driver circuit 100. Connecting the back gate terminal of semiconducting oxide transistor 124 to VGL in this way enables transistor 124 to exhibit less threshold voltage shift over time, which is technically advantageous and beneficial by improving the overall reliability of gate driver circuit 100. Similar to the embodiment of FIG. 4A, the gate terminal of transistor 116 that receives clock signal CLK1 has minimal capacitive loading, which reduces the overall dynamic power consumption of gate driver circuit 100 in FIG. 4C.

FIG. 4D is a circuit diagram illustrating another embodiment of gate driver circuit 100. As shown in FIG. 4D, gate driver circuit 100 may include silicon transistors 112, 116, and 118 (e.g., p-type LTPS transistors), semiconducting oxide transistors 111, 117, and 150 (e.g., n-type oxide transistors), and capacitor CB. Semiconducting oxide transistor 111 can have a source terminal coupled to the VGL power supply line 106, a drain terminal coupled to the output port of gate driver circuit 100, a front gate terminal coupled to node QB, and a back gate terminal configured to receive bias voltage VDC. Voltage VDC can represent a static voltage that is preferably lower than voltage VGL. Biasing transistor 111 in this way enables transistor 111 to exhibit less threshold voltage shift over time, which is technically advantageous and beneficial by improving the overall reliability of gate driver circuit 100. In other examples, voltage VDC can be equal to VGL, less than VGL, equal to VGH, between VGL and VGH, or other fixed DC (direct current) voltage or adjustable voltage. If desired, the back gate terminal of transistor 111 can alternatively be shorted to its source terminal to receive low voltage VGL.

Transistor 112 can have a drain terminal coupled to the output port of gate driver circuit 100, a gate terminal coupled to node QB, and a source terminal coupled to positive power supply line 108′ (e.g., a power supply terminal on which a high voltage VGH′ is provided). For example, power supply voltage VGH′ may be different than VGH, less than VGH, greater than VGH, equal to VGH, or other high voltage. Capacitor CB may be coupled across the gate and source terminals of transistor 112. Transistors 111 and 112 that are directly coupled to the output port are sometimes referred to as output transistors.

Transistor 118 can have a source terminal coupled to power supply line 108′, a drain terminal coupled to node QB, and a gate terminal coupled to node Q2. Semiconducting oxide transistor 150 may have a drain terminal coupled to node QB, a source terminal coupled to the VGL power line, a front gate terminal coupled to node Q2, and a back gate terminal configured to receive bias voltage VDC. Transistors 118 and 150 coupled together in series in this way form a complementary inverter. Transistor 116 may have a first source-drain terminal coupled to node Q2, a gate terminal configured to receive clock signal CLK, and a second source-drain terminal configured to receive a gate start signal GST (e.g., if gate driver circuit 100 is the first or second driver in the gate driver chain) or signal OUT(n−1), which is the gate output signal from the gate driver circuit in a preceding row.

Semiconducting oxide transistor 117 may be coupled in parallel with transistor 116. In particular, semiconducting oxide transistor 117 may have a first source-drain terminal coupled to node Q2, a second source-drain terminal configured to receive gate start signal GST or OUT(n−1), a front gate terminal configured to receive an inverted clock signal CLKB (e.g., an inverted version of CLK), and a back gate terminal configured to receive bias voltage VDC. To generate the inverted clock signal CLKB, gate driver circuit 100 can include a clock inverter circuit 160. Clock inverter circuit 160 may include a p-type LTPS transistor 162 coupled in series with n-type semiconducting oxide transistor 164. In particular, transistor 162 has a source terminal coupled to VGH, a gate terminal configured to receive clock signal CLK, and a drain terminal. On the other hand, semiconducting oxide transistor 164 has a drain terminal coupled to transistor 162, a source terminal coupled to VGL, a front gate terminal configured to receive clock signal CLK, and a back gate terminal configured to receive bias voltage VDC. The inverted clock signal CLKB may be generated at the node connected between transistors 162 and 164.

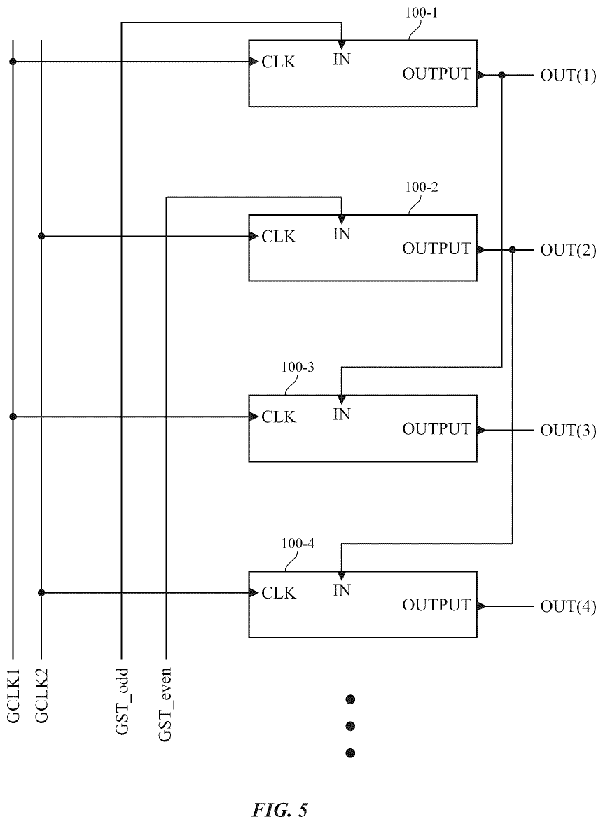

The gate driver circuits 100 of FIGS. 4A, 4B, 4C, and 4D all share the same or similar functionality. FIG. 5 is a diagram showing illustrative gate driver circuitry 34 having a chain of gate driver circuits including at least gate driver circuits 100-1, 100-2, 100-3, and 100-4 in accordance with some embodiments. The gate driver circuits 100 of FIG. 5 can represent gate driver circuits of the type shown in FIG. 4A, 4B, 4C, or 4B. As shown in FIG. 5, the first gate driver circuit 100-1 is configured to generate a first gate output signal OUT(1); the second gate driver circuit 100-2 is configured to generate a second gate output signal OUT(2); the third gate driver circuit 100-3 is configured to generate a third gate output signal OUT(3); the fourth gate driver circuit 100-4 is configured to generate a fourth gate output signal OUT(4); and so on. In general, gate driver circuitry 34 can include hundreds or thousands of gate driver circuits 100 coupled together in a chain.

Gate driver circuitry 34 of FIG. 5 can be controlled using two global clock signals GCLK1 and GCLK2 and two gate start signals GST_odd and GST_even. The odd gate driver circuits (e.g., gate drivers 100-1, 100-3, and so on) can each have a transistor 116 configured to receive signal GCLK1, whereas the even gate driver circuits (e.g., gate drivers 100-2, 100-4, and so on) can each have a transistor 116 configured to receive signal GCLK2. Thus, each gate driver circuit 100 receives only one clock signal (e.g., either GCLK1 or GCLK2). The first gate driver circuit 100-1 in the chain can receive first gate start signal GST_odd (e.g., at a source-drain terminal of transistor 116 as shown in FIGS. 4A, 4B, 4C, and 4D). The second gate driver circuit 100-2 in the chain can receive second gate start signal GST_even (e.g., at a source-drain terminal of transistor 116 as shown in FIGS. 4A, 4B, 4C, and 4D). The third gate driver circuit 100-3 in the chain can receive gate output signal OUT(1) from two rows prior. The fourth gate driver circuit 100-4 in the chain can receive gate output signal OUT(2) from two rows prior. Thus, in general, the embodiment of FIG. 5 shows each gate driver circuit in row (n) being configured to receive OUT(n−2) from two rows above. This is merely illustrative. Gate driver circuitry 34 can be modified such that a gate driver in row (n) might receive a gate output signal and/or a carry output signal from one row above, from two rows above, from three rows above, from four or more rows above, from one row below, from two rows below, from three rows below, or from four or more rows below, etc.

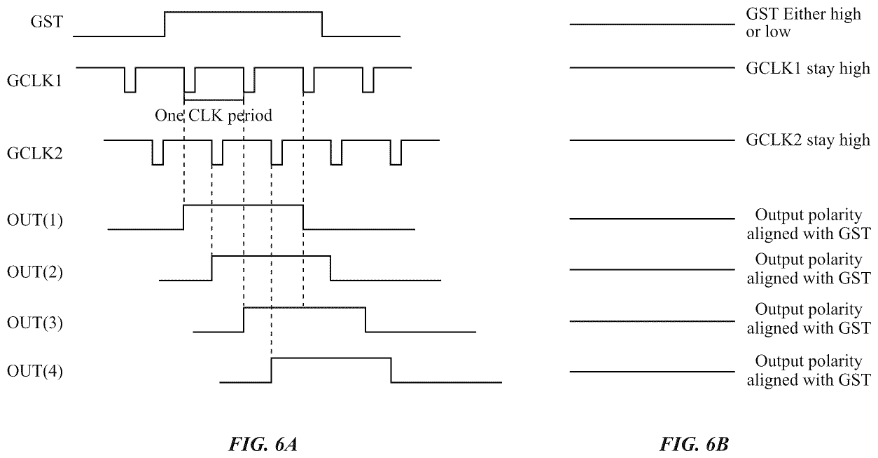

FIG. 6A is a timing diagram illustrating the operation of gate driver circuits of the type shown in FIG. 5 during an active frame in accordance with some embodiments. As shown in FIG. 6A, GCLK2 is a delayed version of GCLK1. The gate output signals OUT(1), OUT(2), OUT(3), and OUT(4) are all at least partially overlapping in time (e.g., the rising edge of OUT(4) occurs before the falling edge of OUT(1)). The pulse width of the gate output signals is equal to an integer number M times the clock period of GCLK1 (or GCLK2). The actual value of integer M is determined by the pulse width of the gate start signal GST. A longer gate start pulse would lengthen the corresponding pulse width of each gate output signal. A shorter gate start pulse would truncate the corresponding pulse width of each gate output signal.

FIG. 6B is a timing diagram illustrating the operation of gate driver circuits of the type shown in FIG. 5 during a blanking frame in accordance with some embodiments. As shown in FIG. 6B, the gate start signal GST can be driven either high or low, the global clock signals GCLK1 and GCLK2 should stop toggling and remain high during the blanking period, and the output polarity of each gate driver circuit 100 can be aligned with the polarity of the GST signal (e.g., if GST is held high during the blanking period, then all of the gate output signals will be driven high, or vice versa).

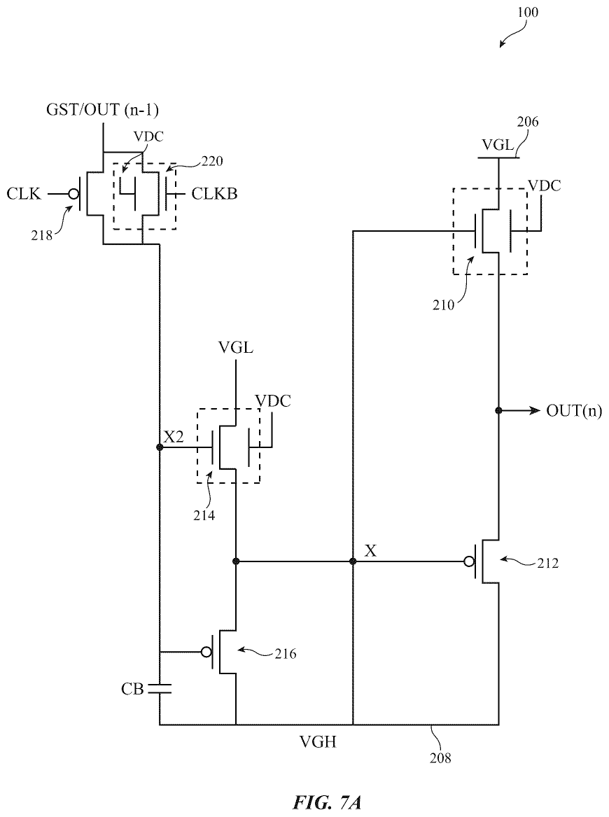

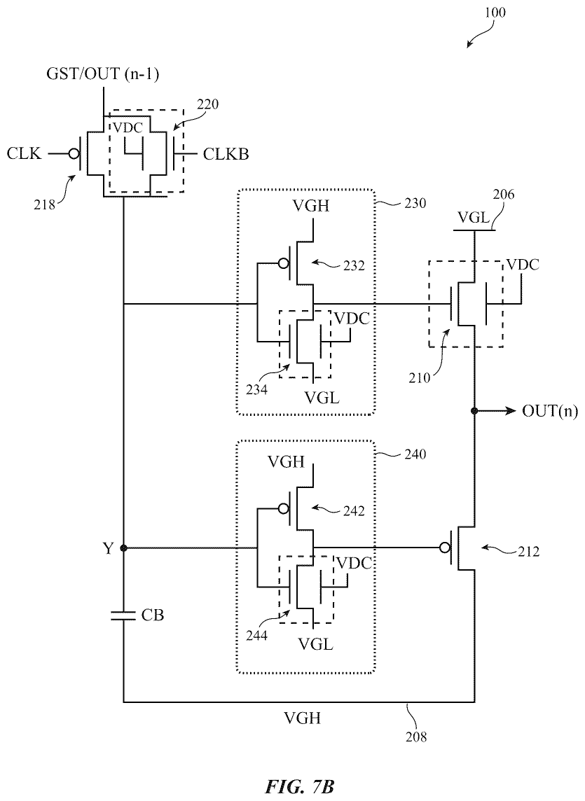

The examples of FIGS. 4-6 that collectively employ two clock signals (see, e.g., GCLK1 and GCLK2 in FIGS. 5-6) that are partially delayed or offset with respect to each other are illustrative and are not intended to limit the scope of the present embodiments. FIG. 7A shows another embodiment of gate driver circuit 100 that can be used in a chain of gate drivers collectively employing two clock signals that are offset by 180° with respect to each other. As shown in FIG. 7A, gate driver circuit 100 may include silicon transistors 212, 216, and 218 (e.g., p-type LTPS transistors), semiconducting oxide transistors 210, 214, and 220 (e.g., n-type oxide transistors), and capacitor CB.

Semiconducting oxide transistor 210 can have a source terminal coupled to the VGL power supply line 206, a drain terminal coupled to the output port of gate driver circuit 100, a front gate terminal coupled to node X, and a back gate terminal configured to receive bias voltage VDC. Voltage VDC can represent a static voltage that is preferably lower than voltage VGL. Biasing transistor 210 in this way enables transistor 210 to exhibit less threshold voltage shift over time, which is technically advantageous and beneficial by improving the overall reliability of gate driver circuit 100. In other examples, voltage VDC can be equal to VGL, less than VGL, equal to VGH, between VGL and VGH, or other fixed DC (direct current) voltage or adjustable voltage. If desired, the back gate terminal of transistor 210 can alternatively be shorted to its source terminal to receive low voltage VGL. Transistor 212 can have a drain terminal coupled to the output port of gate driver circuit 100, a gate terminal coupled to node X, and a source terminal coupled to positive power supply line 208 (e.g., a power supply terminal on which a high voltage VGH is provided). Transistors 210 and 212 that are directly coupled to the output port are sometimes referred to as output transistors.

Transistor 216 can have a source terminal coupled to power supply line 208, a drain terminal coupled to node X, and a gate terminal coupled to node X2. Capacitor CB may be coupled across the gate and source terminals of transistor 216. Capacitor CB is optional. Semiconducting oxide transistor 214 may have a drain terminal coupled to node X, a source terminal coupled to the VGL power line, a front gate terminal coupled to node X2, and a back gate terminal configured to receive bias voltage VDC. Transistors 214 and 216 coupled together in series in this way form a complementary inverter.

Transistor 218 may have a first source-drain terminal coupled to node X2, a gate terminal configured to receive clock signal CLK, and a second source-drain terminal configured to receive a gate start signal GST (e.g., if gate driver circuit 100 is the first or second driver in the gate driver chain) or signal OUT(n−1), which is the gate output signal from the gate driver circuit in a preceding row. Semiconducting oxide transistor 220 may be coupled in parallel with transistor 218. In particular, semiconducting oxide transistor 220 may have a first source-drain terminal coupled to node X2, a second source-drain terminal configured to receive gate start signal GST or OUT(n−1), a front gate terminal configured to receive an inverted clock signal CLKB (e.g., an inverted version of CLK), and a back gate terminal configured to receive bias voltage VDC.

The arrangement shown in FIG. 7A in which the back gate terminals of semiconducting oxide transistors 210, 214, and 220 are configured to receive voltage VDC is exemplary. If desired, the back gate terminals of one or more of these semiconducting oxide transistors can be shorted to their respective source terminals or can be shorted to their respective front (top) gate terminals. The gate terminal of transistor 218 that receives clock signal CLK and the gate terminal of transistor 220 that receives clock signal CLKB have minimal capacitive loading, which helps to reduce the overall dynamic power consumption of gate driver circuit 100 of the type shown in FIG. 7A. For gate driver circuit 100 of FIG. 7A to operate properly, clock signal CLK may need to have a 50% duty cycle (e.g., clock signal CLK should have high and low clock phases of equal duration).

The embodiment of FIG. 7A in which gate driver circuit 100 includes one inverting circuit formed from transistors 214 and 216 to drive node X is illustrative. FIG. 7B shows another embodiment of gate driver circuit 100 that includes two inverting circuits 230 and 240 for separately driving the gate terminals of output transistors 210 and 212. As shown in FIG. 7B, gate driver circuit 100 may include silicon transistors 212 and 218 (e.g., p-type LTPS transistors), semiconducting oxide transistors 210 and 220 (e.g., n-type oxide transistors), inverting circuits 230 and 240, and capacitor CB.

Semiconducting oxide transistor 210 can have a source terminal coupled to the VGL power supply line 206, a drain terminal coupled to the output port of gate driver circuit 100, a front gate terminal coupled to an output of inverter 230, and a back gate terminal configured to receive bias voltage VDC. Voltage VDC can represent a static voltage that is preferably lower than voltage VGL. Biasing transistor 210 in this way enables transistor 210 to exhibit less threshold voltage shift over time, which is technically advantageous and beneficial by improving the overall reliability of gate driver circuit 100. In other examples, voltage VDC can be equal to VGL, less than VGL, equal to VGH, between VGL and VGH, or other fixed DC (direct current) voltage or adjustable voltage. If desired, the back gate terminal of transistor 210 can alternatively be shorted to its source terminal to receive low voltage VGL or shorted to its front gate terminal. Transistor 212 can have a drain terminal coupled to the output port of gate driver circuit 100, a gate terminal coupled to an output of inverter 240, and a source terminal coupled to positive power supply line 208 (e.g., a power supply terminal on which a high voltage VGH is provided). Transistors 210 and 212 that are directly coupled to the output port are sometimes referred to as output transistors.

Inverter 230 may have a p-type silicon transistor 232 and an n-type semiconducting oxide transistor 234 coupled in series between VGH and VGL. Semiconducting oxide transistor 234 may have a back gate terminal configured to receive voltage VDC. The front gate terminals of the inverter transistors 232 and 233 can be coupled to node Y. Inverter 240 may have a p-type silicon transistor 242 and an n-type semiconducting oxide transistor 244 coupled in series between VGH and VGL. Semiconducting oxide transistor 244 may have a back gate terminal configured to receive voltage VDC. The front gate terminals of the inverter transistors 242 and 244 can be coupled to node Y. Capacitor CB may be coupled across node Y and the VGH power line 208. Capacitor CB is optional.

Transistor 218 may have a first source-drain terminal coupled to node Y, a gate terminal configured to receive clock signal CLK, and a second source-drain terminal configured to receive a gate start signal GST (e.g., if gate driver circuit 100 is the first or second driver in the gate driver chain) or signal OUT(n−1), which is the gate output signal from the gate driver circuit in a preceding row. Semiconducting oxide transistor 220 may be coupled in parallel with transistor 218. In particular, semiconducting oxide transistor 220 may have a first source-drain terminal coupled to node Y, a second source-drain terminal configured to receive gate start signal GST or OUT(n−1), a front gate terminal configured to receive an inverted clock signal CLKB (e.g., an inverted version of CLK), and a back gate terminal configured to receive bias voltage VDC. For gate driver circuit 100 of FIG. 7B to operate properly, clock signal CLK may need to have a 50% duty cycle (e.g., clock signal CLK should have high and low clock phases of equal duration).

The arrangement shown in FIG. 7B in which the back gate terminals of semiconducting oxide transistors 210, 234, 244, and 220 are configured to receive voltage VDC is exemplary. If desired, the back gate terminals of one or more of these semiconducting oxide transistors can be shorted to their respective source terminals or can be shorted to their respective front (top) gate terminals. The gate terminal of transistor 218 that receives clock signal CLK and the gate terminal of transistor 220 that receives clock signal CLKB have minimal capacitive loading, which helps to reduce the overall dynamic power consumption of gate driver circuit 100 of the type shown in FIG. 7B. Compared to the design of FIG. 7A, gate driver circuit 100 of FIG. 7B can operate at even lower power levels at the expense of slightly increased circuit area.

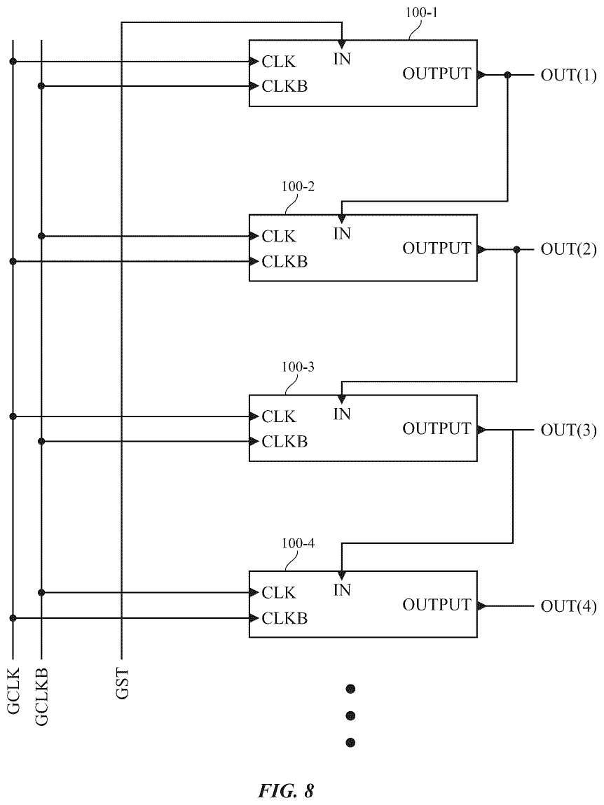

The gate driver circuits 100 of FIGS. 7A and 7B all share the same or similar functionality. FIG. 8 is a diagram showing illustrative gate driver circuitry 34 having a chain of gate driver circuits including at least gate driver circuits 100-1, 100-2, 100-3, and 100-4 in accordance with some embodiments. The gate driver circuits 100 of FIG. 8 can represent gate driver circuits of the type shown in FIG. 7A or 7B. As shown in FIG. 8, the first gate driver circuit 100-1 is configured to generate a first gate output signal OUT(1); the second gate driver circuit 100-2 is configured to generate a second gate output signal OUT(2); the third gate driver circuit 100-3 is configured to generate a third gate output signal OUT(3); the fourth gate driver circuit 100-4 is configured to generate a fourth gate output signal OUT(4); and so on. In general, gate driver circuitry 34 can include hundreds or thousands of gate driver circuits 100 coupled together in a chain.

Gate driver circuitry 34 of FIG. 8 can be controlled using a first global clock signal GCLK and a second global clock signal GCLKB that is an inverted version of GCLK (i.e., GCLKB is offset or delayed by 180° relative to GCLK). The odd gate driver circuits (e.g., gate drivers 100-1, 100-3, and so on) can each have a transistor 218 configured to receive signal GCLK and a transistor 220 configured to receive signal GCLKB (e.g., the CLK input receives GCLK and the CLKB input receives GCLKB). The even gate driver circuits (e.g., gate drivers 100-2, 100-4, and so on) can each have a transistor 218 configured to receive signal GCLKB and a transistor 220 configured to receive signal GCLK (e.g., the CLK input receives GCLKB and the CLKB input receives GCLK).

The first gate driver circuit 100-1 in the chain can receive a gate start signal GST (e.g., at a source-drain terminal of transistor 218 as shown in FIGS. 7A and 7B). The second gate driver circuit 100-2 in the chain can receive gate output signal OUT(1) from one row prior. The third gate driver circuit 100-3 in the chain can receive gate output signal OUT(2) from one row prior. Thus, in general, the embodiment of FIG. 8 shows each gate driver circuit in row (n) being configured to receive OUT(n−1) from the preceding row. This is merely illustrative. Gate driver circuitry 34 can be modified such that a gate driver in row (n) might receive a gate output signal and/or a carry output signal from two rows above, from three rows above, from four or more rows above, from one row below, from two rows below, from three rows below, or from four or more rows below, etc.

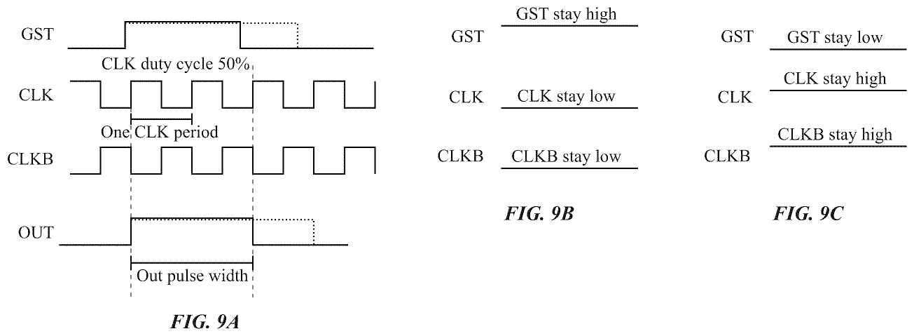

FIG. 9A is a timing diagram illustrating the operation of gate driver circuits of the type shown in FIG. 8 during an active frame in accordance with some embodiments. As shown in FIG. 9A, CLKB is a delayed version of CLK. For the odd gate drivers, the signal waveforms of CLK and CLKB will be equal to GCLK and GCLKB, respectively. For the even gate drivers, the signal waveforms of CLK and CLKB will be equal to GCLKB and GCLK, respectively. The pulse width of the gate output signal OUT is equal to an integer number M times the clock period of CLK. The actual value of integer M is determined by the pulse width of the gate start signal GST. A longer gate start pulse would lengthen the corresponding pulse width of the gate output signal. A shorter gate start pulse would truncate the corresponding pulse width of the gate output signal.

FIG. 9B is a timing diagram illustrating the operation of gate driver circuit 100 of the type shown in FIG. 7A during a blanking frame in accordance with some embodiments. As shown in FIG. 9B, the gate start signal GST can be driven high, the global clock signals CLK and CLKB should stop toggling and remain low during the blanking period.

FIG. 9C is a timing diagram illustrating the operation of gate driver circuit 100 of the type shown in FIG. 7B during a blanking frame in accordance with some embodiments. As shown in FIG. 9C, the gate start signal GST can be driven low, the global clock signals CLK and CLKB should stop toggling and remain high during the blanking period.

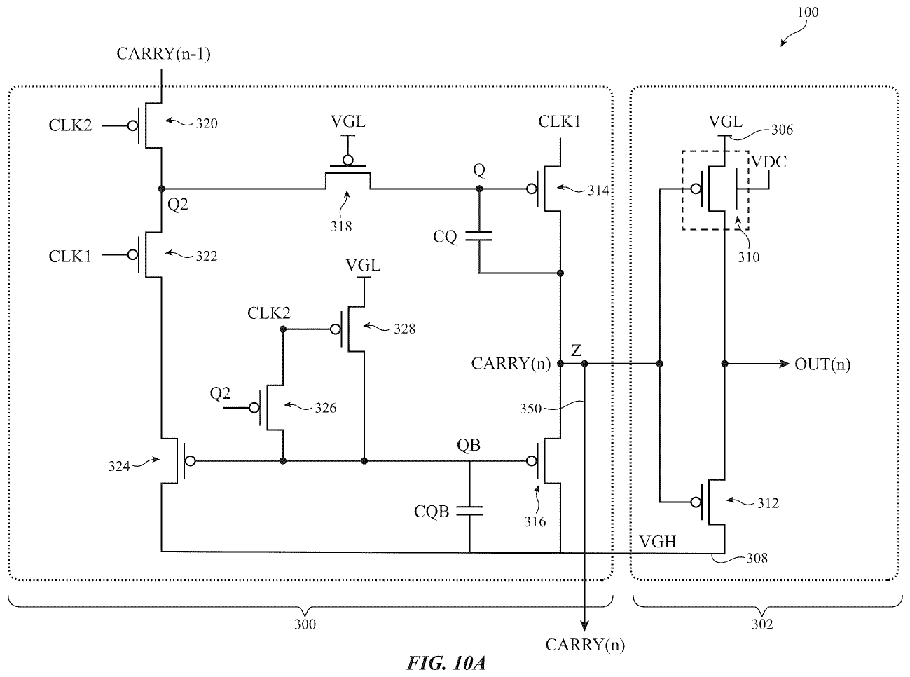

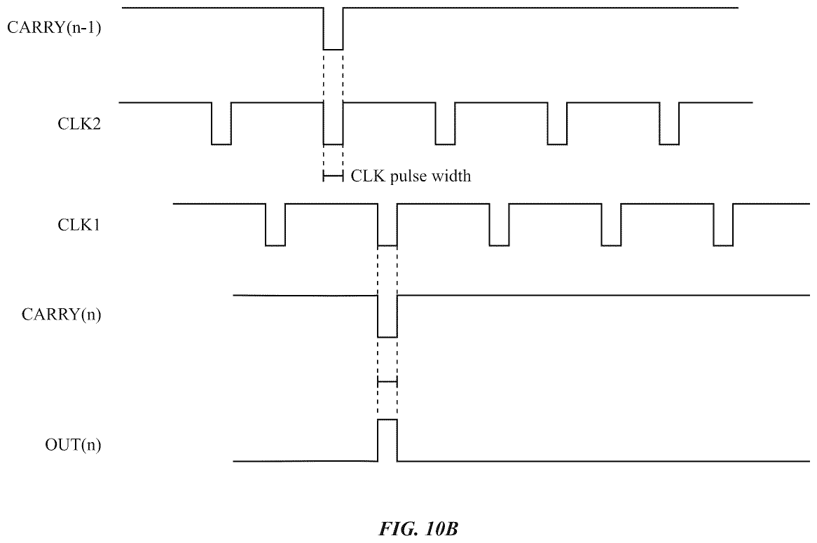

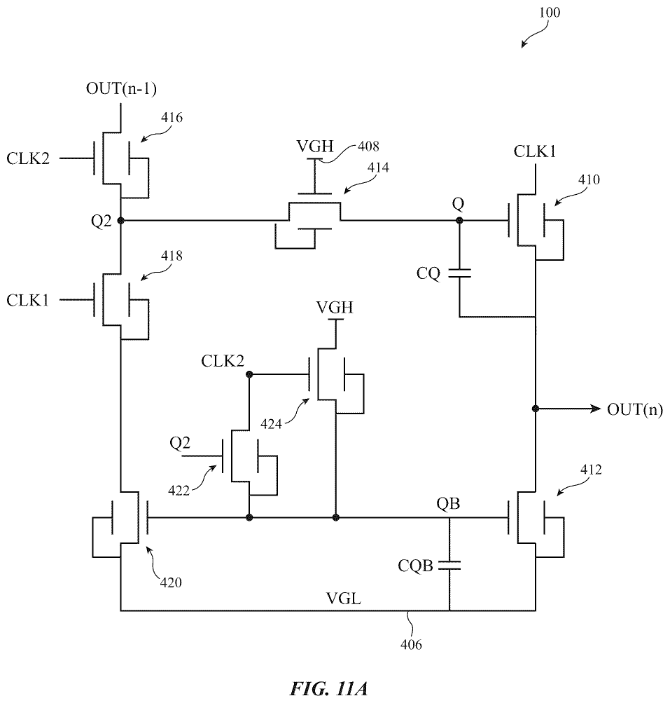

The embodiments of FIGS. 4-9 in which the pulse width of the gate output signal is controlled by the gate start signal is exemplary. FIG. 10A shows another embodiment of gate driver 100 in which the pulse width of the gate output signal can be tuned by the pulse width of the clock signal itself. As shown in FIG. 10A, gate driver circuit 100 may include a logic subcircuit (portion) 300 and an output buffer subcircuit (portion) 302.

Output buffer subcircuit 302 may include an n-type semiconducting oxide transistor 310 and a p-type silicon transistor 312 coupled in series between power supply lines 306 and 308. Semiconducting oxide transistor 310 may have a source terminal coupled to a low voltage line 306 (e.g., a power supply terminal on which low voltage VGL is provided), a drain terminal coupled to the output port of gate driver circuit 100 (e.g., an output terminal on which gate output signal OUT(n) is provided), a front gate terminal coupled to node Z, and a back gate terminal configured to receive bias voltage VDC. Voltage VDC can represent a static voltage that is preferably lower than voltage VGL. Biasing transistor 310 in this way enables transistor 310 to exhibit less threshold voltage shift over time, which is technically advantageous and beneficial by improving the overall reliability of gate driver circuit 100. In other examples, voltage VDC can be equal to VGL, less than VGL, equal to VGH, between VGL and VGH, or other fixed DC (direct current) voltage or adjustable voltage. If desired, the back gate terminal of transistor 310 can alternatively be shorted to its source terminal to receive low voltage VGL or shorted to its front gate terminal.

Silicon transistor 312 may have a drain terminal coupled to the gate driver output port, a gate terminal coupled to node Z, and a source terminal coupled to a high voltage line 308 (e.g., a power supply terminal on which high voltage VGH is provided). A carry signal such as CARRY(n) can be generated at node Z. The carry signal can be fed to a gate driver circuit in another row (see, e.g., via path 350). The carry signal CARRY(n) can be generated by logic subcircuit 300. The logic subcircuit 300 can therefore perform a shift register function.

Logic subcircuit 300 can include capacitors CQ and CQB and only silicon transistors 314, 316, 318, 320, 322, 324, 326, and 328 (e.g., p-type LTPS transistors). Silicon transistor 314 may have a first source-drain terminal coupled to node Z, a second source-drain terminal configured to receive a first clock signal CLK1, and a gate terminal coupled to node Q. Capacitor CQ can be coupled across nodes Q and Z. Silicon transistor 316 may have a first source-drain terminal coupled to node Z, a second source-drain terminal coupled to the VGH power line 308, and a gate terminal coupled to node QB. Capacitor CQB may be coupled across node QB and power line 308. The voltage on node QB may generally be inverted with respect to the voltage on node Q (e.g., nodes Q and QB can be complementary nodes with inverted voltage levels).

Transistor 318 may have a first source-drain terminal coupled to node Q, a gate terminal configured to receive the VGL voltage, and a second source-drain terminal coupled to node Q2. Transistor 320 may have a first source-drain terminal coupled to node Q2, a gate terminal configured to receive a second clock signal CLK2, and a second source-drain terminal configured to receive signal CARRY(n−1) (e.g., the carry signal output from gate driver 100 of the preceding row). Transistor 322 may be coupled in series with transistor 320. In particular, transistor 322 may have a first source-drain terminal coupled to node Q2, a gate terminal configured to receive clock signal CLK1, and a second source-drain terminal coupled to transistor 324. Transistor 324 may be coupled in series with transistor 322. Transistor 324 may have a drain terminal coupled to transistor 322, a source terminal coupled to the VGH power line 308, and a gate terminal coupled to node QB. Transistor 326 may have a first source-drain terminal coupled to node QB, a gate terminal coupled to node Q2, and a second source-drain terminal configured to receive clock signal CLK2. Transistor 328 may have a first source-drain terminal coupled to node QB, a second source-drain terminal configured to the VGL power line, and a gate terminal configured to receive clock signal CLK2.

FIG. 10B is a timing diagram illustrating the operation of gate driver circuit 100 of the type described in connection with FIG. 10A. As shown in FIG. 10B, the carry signal CARRY(n−1) may be synchronized with the CLK2 signal and may have an active low pulse width set by the low clock phase of CLK2. Similarly, the carry signal CARRY(n) may be synchronized with the CLK1 signal and may have an active low pulse width set by the low clock phase of CLK1. The corresponding gate output signal OUT(n) may be synchronized with the carry signal CARRY(n). Gate output signal OUT(n) can have a relatively short positive (active high) pulse width set by the pulse width of the clock signals. As examples, the low phase pulse width of CLK1 (or CLK2) can be set to 1 microsecond (μs), 2 μs, 3 μs, 4 μs, 5 μs, 1-5 μs, more than 5 μs, less than 1 μs, 5-10 μs, more than 10 μs, 10-100 μs, or other programmable duration. The terminology “active high” may refer to a type of operation in which a high voltage asserts, selects, or activates the corresponding transistors receiving that signal.

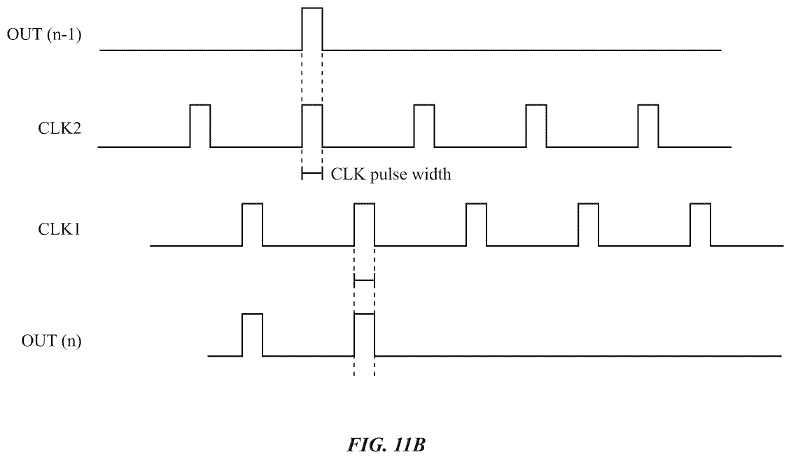

The embodiment of FIG. 10A that includes only one semiconducting oxide transistor 310 is exemplary. FIG. 11A shows another embodiment of gate driver circuit 100 in which all of the thin-film transistors are implemented as semiconducting oxide transistors. As shown in FIG. 11A, gate driver circuit 100 may include capacitors CQ and CQB and only semiconducting oxide transistors 410, 412, 414, 416, 418, 420, 422, and 424. Transistor 410 may have a first source-drain terminal configured to receive clock signal CLK1, a second source-drain terminal coupled to the output port of gate driver circuit 100, a front gate terminal coupled to node Q, and a back gate terminal shorted to its own second source-drain terminal. Capacitor CQ may be coupled across node Q and the output port of gate driver 100. Transistor 412 may have a drain terminal coupled to the output port of gate driver 100, a source terminal coupled to a power supply line 406 (e.g., a power supply terminal on which low voltage VGL is provided), a front gate terminal coupled to node QB, and a back gate terminal coupled to the VGL power line 406. Capacitor CQB may be coupled across the gate and source terminals of transistor 412.

Transistor 408 may have a first source-drain terminal coupled to node Q, a second source-drain terminal coupled to node Q2, a front gate terminal coupled to power supply line 408 (e.g., a power supply terminal on which high voltage VGH is provided), and a back gate terminal shorted to its own second source-drain terminal. Transistor 416 may have a first source-drain terminal coupled to node Q2, a second source-drain terminal configured to receive signal OUT(n−1) (e.g., the gate output signal generated by a gate driver of a preceding row), a front gate terminal configured to receive clock signal CLK2, and a back gate terminal shorted to its own first source-drain terminal. Transistor 418 may be coupled in series with transistor 416. In particular, transistor 418 may have a first source-drain terminal coupled to node Q2, a second source-drain terminal coupled to transistor 420, a front gate terminal configured to receive clock signal CLK1, and a back gate terminal shorted to its own second source-drain terminal.

Transistor 420 may be coupled in series with transistor 418. In particular, transistor 420 may have a drain terminal coupled to transistor 418, a source terminal coupled to the VGL ground line 406, a front gate terminal coupled to node QB, and a back gate terminal shorted to its own source terminal. Transistor 422 may have a first source-drain terminal coupled to node QB, a second source-drain terminal configured to receive clock signal CLK2, a front gate terminal coupled to node Q2, and a back gate terminal shorted to its own first source-drain terminal. Transistor 424 may have a drain terminal coupled to the VGH power line, a source terminal coupled to node QB, a front gate terminal configured to receive clock signal CLK2, and a back gate terminal shorted to its own source terminal.

The example of FIG. 11A in which all of the semiconducting oxide transistors in gate driver circuit 100 have back gate terminals shorted to its own source terminal is illustrative. If desired, one or more of these semiconducting oxide transistors can have its back gate terminal shorted to its top gate terminal, configured to receive VGL, configured to receive VGH, or configured to receive bias voltage VDC.

FIG. 11B is a timing diagram illustrating the operation of gate driver circuit 100 of the type described in connection with FIG. 11A. As shown in FIG. 11B, signal OUT(n−1) may be synchronized with the CLK2 signal and may have an active high low pulse width set by the high clock phase of CLK2. The corresponding gate output signal OUT(n) may be synchronized with the CLK1 signal and may have an active high pulse width set by the high clock phase of CLK1. As examples, the high phase pulse width of CLK1 (or CLK2) can be set to 1 microsecond ( μ), 2 μs, 3 μs, 4 μs, 5 μs, 1-5 μs, more than 5 μs, less than 1 μs, 5-10 μs, more than 10 μs, 10-100 μs, or other programmable duration. The terminology “active high” may refer to a type of operation in which a high voltage asserts, selects, or activates the corresponding transistors receiving that signal.

The foregoing is merely illustrative and various modifications can be made to the described embodiments. The foregoing embodiments may be implemented individually or in any combination.

What is claimed is:

1. A gate driver circuit comprising:
a first transistor having a drain terminal coupled to a first power supply line, a source terminal coupled to an output port of the gate driver circuit, and a gate terminal, wherein a gate output signal is generated at the output port and is provided to a plurality of display pixels;
a second transistor having a drain terminal coupled to the output port, a source terminal coupled to a second power supply line different than the first power supply line, and a gate terminal; and
a semiconducting oxide transistor having a source terminal coupled to the first power supply line or configured to receive a bias voltage, a drain terminal coupled to the gate terminal of the second transistor, a back gate terminal shorted to its source terminal, and a front gate terminal.

2. The gate driver circuit of claim 1, further comprising:
a first capacitor having a first terminal coupled to the gate terminal of the first transistor and having a second terminal coupled to the output port; and
a second capacitor having a first terminal coupled to the gate terminal of the second transistor and having a second terminal coupled to the second power supply line.

3. The gate driver circuit of claim 2, wherein the first and second transistors comprise p-type silicon transistors.

4. The gate driver circuit of claim 2, further comprising:
a third transistor having a first source-drain terminal coupled to the gate terminal of the first transistor, a gate terminal coupled to the first power supply line, and a second source-drain terminal coupled to a node.

5. The gate driver circuit of claim 4, wherein the front gate terminal of the semiconducting oxide transistor is coupled to the node.

6. The gate driver circuit of claim 4, wherein the front gate terminal of the semiconducting oxide transistor is coupled to the gate terminal of the first transistor.

7. The gate driver circuit of claim 6, further comprising:
an additional semiconducting oxide transistor having a source terminal coupled to the first power supply line, a drain terminal coupled to the output port, a front gate terminal coupled to the gate terminal of the second transistor, and a back gate terminal shorted to its source terminal.

8. The gate driver circuit of claim 4, further comprising:
a fourth transistor having a first source-drain terminal coupled to the node, a second source-drain terminal configured to receive a gate start signal or a gate output signal from an additional gate driver circuit, and a gate terminal configured to receive a clock signal; and
a fifth transistor having a drain terminal coupled to the gat terminal of the second transistor, a source terminal coupled to the second power supply line, and a gate terminal coupled to the node.

9. A gate driver circuit comprising:
a first semiconducting oxide transistor having a source terminal coupled to a first power supply line, a drain terminal coupled to an output port of the gate driver circuit, a front gate terminal coupled to a first node, and a back gate terminal configured to receive a bias voltage;
a first silicon transistor having a drain terminal coupled to the output port, a gate terminal coupled to the first node, and a source terminal coupled to a second power supply line different than the first power supply line; and
a capacitor having a first terminal coupled to the first node and having a second terminal coupled to the second power supply line.

10. The gate driver circuit of claim 9, further comprising:
a second semiconducting oxide transistor having a drain terminal coupled to the first node, a source terminal coupled to the first power supply line, a front gate terminal coupled to a second node, and a back gate terminal configured to receive the bias voltage; and
a second silicon transistor having a drain terminal coupled to the first node, a source terminal coupled to the second power supply line, and a gate terminal coupled to the second node.

11. The gate driver circuit of claim 10, further comprising:
a third silicon transistor having a first source-drain terminal coupled to the second node, a gate terminal configured to receive a clock signal, and a second source-drain terminal configured to receive a gate start signal or a gate output signal from an additional gate driver circuit; and
a third semiconducting oxide transistor having a first source-drain terminal coupled to the second node, a second source-drain terminal coupled to the second source-drain terminal of the third silicon transistor, a front gate terminal configured to receive an inverted version of the clock signal, and a back gate terminal configured to receive the bias voltage.

12. A gate driver circuit comprising:
a first semiconducting oxide transistor having a source terminal coupled to a first power supply line, a drain terminal coupled to an output port of the gate driver circuit, a front gate terminal, and a back gate terminal that is configured to receive a bias voltage;
a first silicon transistor having a drain terminal coupled to the output port, a source terminal coupled to a second power supply line different than the first power supply line, and a gate terminal;
an inverter having an output coupled to the gate terminal of the first silicon transistor; and
a capacitor having a first terminal coupled to an input of the inverter and having a second terminal coupled to the second power supply line.

13. The gate driver circuit of claim 12, wherein the inverter comprises:
a second semiconducting oxide transistor having a source terminal coupled to the first power supply line, a drain terminal coupled to the output of the inverter, a front gate terminal coupled to the input of the inverter, and a back gate terminal configured to receive the bias voltage; and
a second silicon transistor having a source terminal coupled to the second power supply line, a drain terminal coupled to the output of the inverter, and a gate terminal coupled to the input of the inverter.

14. The gate driver circuit of claim 13, further comprising:
a third silicon transistor having a first source-drain terminal coupled to the input of the inverter, a second source-drain terminal configured to receive a gate start signal or a gate output signal from an additional gate driver circuit, and a gate terminal configured to receive a clock signal; and
a third semiconducting oxide transistor having a first source-drain terminal coupled to the input of the inverter, a second source-drain terminal coupled to the second source-drain terminal of the third silicon transistor, a front gate terminal configured to receive an inverted version of the clock signal, and a back gate terminal configured to receive the bias voltage.

15. The gate driver circuit of claim 14, further comprising:
an additional inverter having an input coupled to the input of the inverter and having an output coupled to the gate terminal of the first semiconducting oxide transistor.

16. A gate driver circuit comprising:
a first semiconducting oxide transistor having a source terminal coupled to a first power supply line, a drain terminal coupled to an output port of the gate driver circuit, a front gate terminal coupled to a first node, and a back gate terminal configured to receive a bias voltage;
a first silicon transistor having a drain terminal coupled to the output port, a gate terminal coupled to the first node, and a source terminal coupled to a second power supply line different than the first power supply line; and
a logic subcircuit configured to generate a carry signal on the first node, wherein the carry signal is conveyed to an additional gate driver circuit.

17. The gate driver circuit of claim 16, wherein the logic subcircuit comprises:
a second silicon transistor having a first source-drain terminal coupled to the first node, a second source-drain terminal configured to receive a first clock signal, and a gate terminal coupled to a second node;
a first capacitor coupled across the first node and the second node;
a third silicon transistor having a drain terminal coupled to the first node, a source terminal coupled to a second power supply line different than the first power supply line, and a gate terminal coupled to a third node; and
a second capacitor coupled across the third node and the second power supply line.

18. The gate driver circuit of claim 17, wherein the logic subcircuit further comprises:
a fourth silicon transistor having a first source-drain terminal coupled to the second node, a gate terminal coupled to the first power supply line, and a second source-drain terminal coupled to a fourth node;
a fifth silicon transistor having a first source-drain terminal coupled to the fourth node, a second source-drain terminal configured to receive a carry signal from another gate driver circuit in a prior row, and a gate terminal configured to receive a second clock signal different than the first clock signal; and
a sixth silicon transistor coupled in series with the fifth silicon transistor and having a gate terminal configured to receive the first clock signal.

19. The gate driver circuit of claim 18, wherein the logic subcircuit further comprises:
a seventh silicon transistor coupled in series with the sixth transistor and having a gate terminal coupled to the third node;
an eight silicon transistor having a first source-drain terminal coupled to the third node, a gate terminal coupled to the fourth node, and a second source-drain terminal configured to receive the second clock signal; and
a ninth silicon transistor having a drain terminal coupled to the third node, a source terminal coupled to the first power supply line, and a gate terminal configured to receive the second clock signal.

20. A gate driver circuit comprising:
a first semiconducting oxide transistor having a first source-drain terminal configured to receive a first clock signal, a second source-drain terminal coupled to an output port of the gate driver circuit, a front gate terminal coupled to a first node, and a back gate terminal;
a first capacitor coupled across the first node and the output port;
a second semiconducting oxide transistor having a drain terminal coupled to the output port, a source terminal coupled to a first power supply line, a front gate terminal coupled to a second node, and a back gate terminal; and
a second capacitor coupled across the second node and the first power supply line.

21. The gate driver circuit of claim 20, further comprising:
a third semiconducting oxide transistor having a first source-drain terminal coupled to the first node, a second source-drain terminal coupled to a third node, a front gate terminal coupled to a second power supply line different than the first power supply line, and a back gate terminal; and
a fourth semiconducting oxide transistor having a first source-drain terminal coupled to the third node, a second source-drain terminal configured to receive a gate output signal from an additional gate driver circuit, a front gate terminal configured to receive a second clock signal different than the first clock signal, and a back gate terminal.

22. The gate driver circuit of claim 21, further comprising:
a fifth semiconducting oxide transistor coupled in series with the fourth semiconducting oxide transistor and having a front gate terminal configured to receive the first clock signal; and
a sixth semiconducting oxide transistor coupled in series with the fifth semiconducting oxide transistor and having a front gate terminal coupled to the second node.

23. The gate driver circuit of claim 22, further comprising:
a seventh semiconducting oxide transistor having a first source-drain terminal coupled to the second node, a second source-drain terminal configured to receive the second clock signal, a front gate terminal coupled to the fourth node, and a back gate terminal; and
an eight semiconducting oxide transistor having a source terminal coupled to the second node, a drain terminal coupled to the second power supply line, a front gate terminal configured to receive the second clock signal, and a back gate terminal.
